(19) United States
(12) Patent Application Publication
(10) Pub. No.: US 2022/0219364 A1
(43) Pub. Date: Jul. 14, 2022

(54) COVER PLATE INCLUDING PATTERN AND ELECTRONIC DEVICE INCLUDING THE SAME

(71) Applicant: Samsung Electronics Co., Ltd., Gyeonggi-do (KR)

(72) Inventors: Kwangyoun LEE, Gyeonggi-do (KR); Jongsu LEE, Gyeonggi-do (KR); Wonjoong KANG, Gyeonggi-do (KR); Changsu KIM, Gyeonggi-do (KR)

(21) Appl. No.: 17/583,438

(22) Filed: Jan. 25, 2022

Related U.S. Application Data
(63) Continuation of application No. PCT/KR2021/019940, filed on Dec. 27, 2021.

(30) Foreign Application Priority Data
Jan. 13, 2021 (KR) 10-2021-0004369

(51) Int. Cl. B29C 45/37

(52) U.S. Cl. CPC B29C 45/372; B29L 2031/3475

(57) ABSTRACT

According to certain embodiments, a cover plate of an electronic device, comprises: a first pattern formed in a first region of the cover plate; and a second pattern formed in a second region of the cover plate, wherein the first pattern has a first flat part and a first protrusion part protruding at a first height with respect to the first flat part, the first flat part and the first protrusion part being repeatedly arranged, the second pattern has a second flat part and a second protrusion part protruding at a second height with respect to the second flat part, the second flat part and the second protrusion part being repeatedly arranged, and the first flat part of the first pattern and the second flat part of the second pattern are continuously joined to each other at a portion at which the first pattern and the second pattern are connected.

### CROSS-REFERENCE TO RELATED APPLICATION(S)

This application is a continuation of International Application No. PCT/KR2021/019940, filed on Dec. 27, 2021, which claims priority to Korean Patent Application No. 10-2021-0004369, filed on Jan. 13, 2021 in the Korean Intellectual Property Office, the disclosures of which are herein incorporated by reference.

### TECHNICAL FIELD

Certain embodiments disclosed herein relate to a cover plate having a pattern formed thereon, and an electronic device including the cover plate.

### BACKGROUND ART

A micropattern may be formed on a cover plate on the exterior of an electronic device that is aesthetically pleasing.

The micropattern may refer to a micro-scale regular pattern. Light may be reflected in different manners depending on the pattern type. This results in exhibiting different textures. Such a micropattern may be used to provide an aesthetic appearance to the cover plate.

If the micropattern is formed on a UV film, moldings for forming the micropattern on the UV film may be easily damaged. This can make mass production difficult.

If the cover plate is manufactured having a micropattern formed thereon through injection molding, it may be difficult to manufacture a cover plate including different patterns. During injection molding, materials injected into mold cores would likely be solidified. Materials would likely be solidified because it may be difficult to form multiple patterns on a single mold core.

In an attempt to solve this problem, it may be considered to form different patterns on multiple different mold cores. The multiple mold cores can then be to joined to each other. The cover plate can then be injection-molded. However, disposing cooling channels with an injection-molding device including multiple mold cores has disadvantages. In addition, the level difference between the multiple mold cores may degrade continuity of patterns formed on the cover plate.

### SUMMARY

Certain embodiments disclosed herein may provide a cover plate including a pattern.

According to certain embodiments, a cover plate of an electronic device, comprises: a first pattern formed in a first region of the cover plate; and a second pattern formed in a second region of the cover plate, wherein the first pattern has a first flat part and a first protrusion part protruding at a first height with respect to the first flat part, the first flat part and the first protrusion part being repeatedly arranged, the second pattern has a second flat part and a second protrusion part protruding at a second height with respect to the second flat part, the second flat part and the second protrusion part being repeatedly arranged, and the first flat part of the first pattern and the second flat part of the second pattern are continuously joined to each other at a portion at which the first pattern and the second pattern are connected.

According to certain embodiments, a method comprises forming a cover plate on an electronic device by molding a polymer material using a first mold core and a second mold core, forming a first pattern using a first mold pattern in a first region of one surface of a first mold core, and forming a second pattern using a second mold pattern in a second region of the one surface of the first mold core.

According to certain embodiments disclosed herein, a cover plate including multiple patterns may be formed through injection molding such that the part that connects different patterns has no, or no visible difference in texture, and no separate molding or film is necessary to endow patterns. This reduces process costs.

### BRIEF DESCRIPTION OF DRAWINGS

In connection with the description of the drawings, same or similar reference numerals will be used to refer to same or similar elements.

FIG. 1A is a front perspective view of an electronic device according to certain embodiments disclosed in the disclosure;

FIG. 1B is a rear perspective view of the electronic device of FIG. 1A;

FIG. 1C is an exploded perspective view of the electronic device of FIG. 1A;

FIG. 2 and FIG. 3 are perspective views of a cover plate according to certain embodiments disclosed in the disclosure;

FIG. 4 is a partially cut cross sectional view of a cover plate taken along line A-A illustrated in FIG. 2 according to certain embodiments;

FIG. 5 is a schematic view of an injection device for manufacturing a cover plate according to certain embodiments disclosed in the disclosure;

FIG. 6A is a view, which is schematized as a cross sectional view, illustrating a process of forming a mold pattern according to certain embodiments disclosed in the disclosure;

FIG. 6B is a perspective view of a first mold core according to certain embodiments disclosed in the disclosure;

FIG. 7A and FIG. 7B are views illustrating a machining process of a first mold core according to certain embodiments disclosed in the disclosure; and

FIG. 8A and FIG. 8B are views illustrating a machining tool according to certain embodiments disclosed in the disclosure.

FIG. 9 is flow diagram of a method according to certain embodiments disclosed in the disclosure.

### DETAILED DESCRIPTION

It should be appreciated that certain embodiments of the present disclosure and the terms used therein are not intended to limit the technological features set forth herein to particular embodiments and include various changes, equivalents, or replacements for a corresponding embodiment.

With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

### BRIEF DESCRIPTION OF REFERENCE NUMERALS

200: Cover plate
201: First region
202: Second region
210: First pattern
220: Second pattern

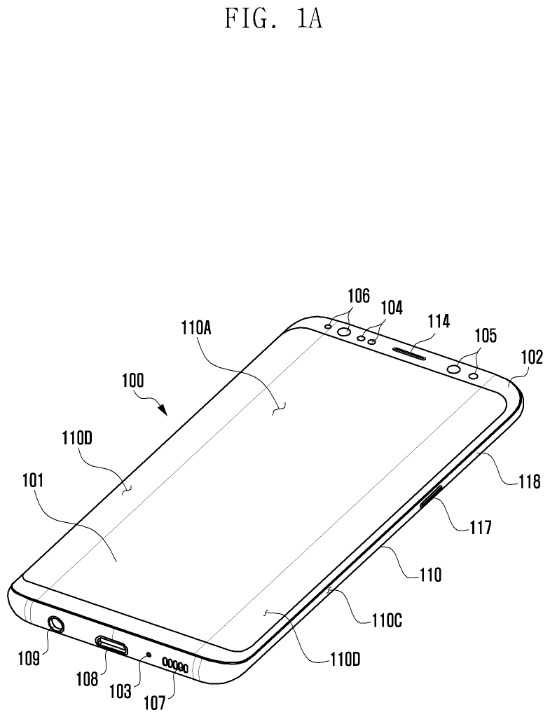

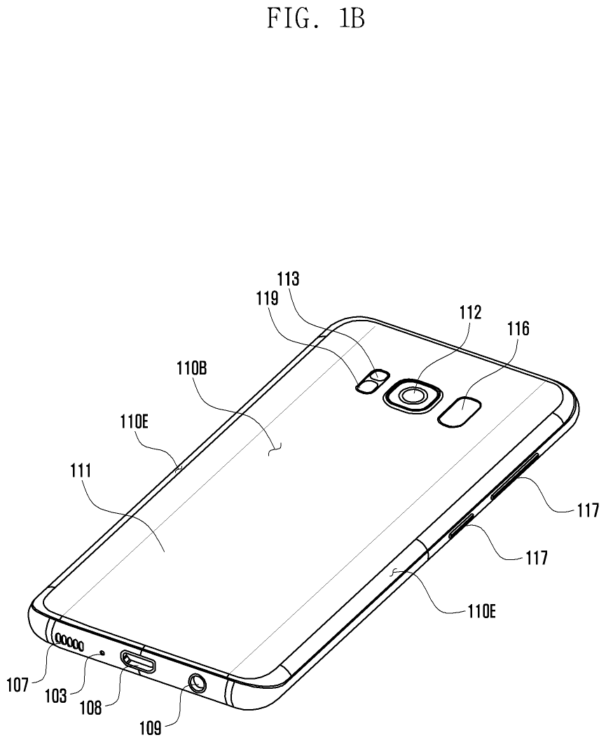

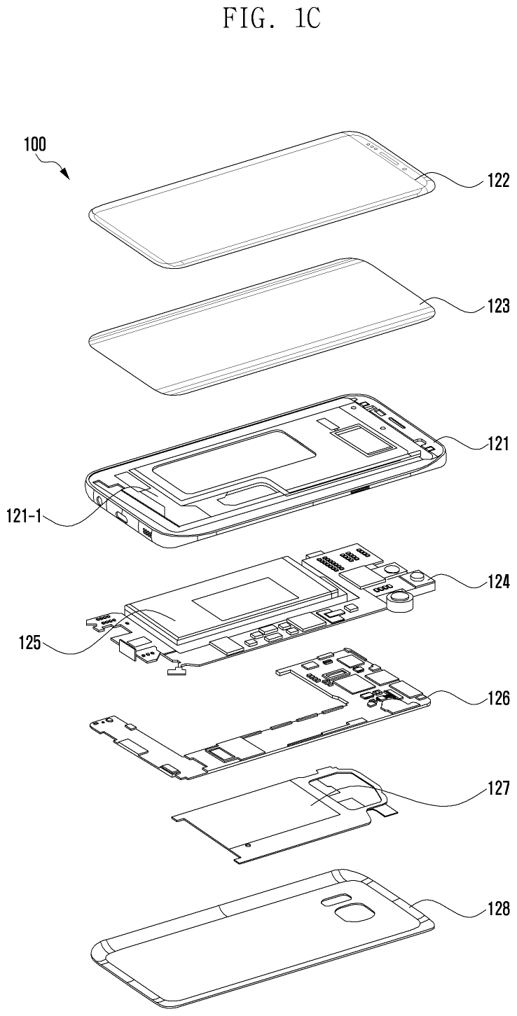

FIGS. 1A to 1C describe an electronic device that can have a cover plate. The appearance of the electronic device can be improved by forming a micropattern on the cover plate.

Electronic Device

Referring to FIGS. 1A, 1B, and 1C, according to an embodiment, an electronic device 100 may include a housing 110 that includes a first surface (or front surface) 110A, a second surface (or rear surface) 110B, and a lateral surface 110C that surrounds a space between the first surface 110A and the second surface 110B. According to another embodiment, the housing 110 may refer to a structure that forms a part of the first surface 110A, the second surface 110B, and the lateral surface 110C. According to an embodiment, the first surface 110A may be formed of a front plate 102 (e.g., a glass plate or polymer plate coated with a variety of coating layers) at least a part of which is substantially transparent. The second surface 110B may be formed of a rear plate 111 which is substantially opaque. The rear plate 111 may be formed of, for example, coated or colored glass, ceramic, polymer, metal (e.g., aluminum, stainless steel (STS), or magnesium), or any combination thereof. The lateral surface 110C may be formed of a lateral bezel structure (or “lateral member”) 118 which is combined with the front plate 102 and the rear plate 111 and includes a metal and/or polymer. The rear plate 111 and the lateral bezel structure 118 may be integrally formed and may be of the same material (e.g., a metallic material such as aluminum).

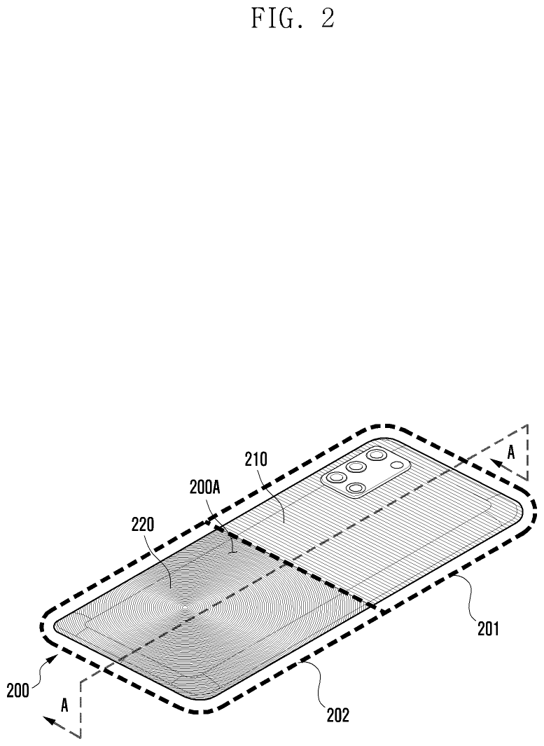

In the shown embodiment, the front plate 102 may include two first regions 110D disposed at long edges thereof, respectively, and bent and extended seamlessly from the first surface 110A toward the rear plate 111. In the shown embodiment, the rear plate 111 may include two second regions 110E disposed at long edges thereof, respectively, and bent and extended seamlessly from the second surface 110B toward the front plate 102 (refer to FIG. 2). In certain embodiments, the front plate 102 (or the rear plate 111) may include only one of the first regions 110D (or of the second regions 110E). In certain embodiments, the first regions 110D or the second regions 110E may be omitted in part. In the embodiments, when viewed from a lateral side of the electronic device 100, the lateral bezel structure 118 may have a first thickness (or width) on a lateral side where one of the first regions 110D or one of the second regions 110E is not included, and may have a second thickness, being less than the first thickness, on another lateral side where one of the first regions 110D or one of the second regions 110E is included.

According to an embodiment, the electronic device 100 may include at least one of a display 101, audio modules 103, 107 and 114, sensor modules 104, 116 and 119, camera modules 105, 112 and 113, key input devices 117, a light emitting device 106, and connector holes 108 and 109. In certain embodiments, the electronic device 100 may omit at least one (e.g., the key input devices 117 or the light emitting device 106) of the above components, or may further include other components.

The display 101 may be exposed through a substantial portion of the front plate 102, for example. In certain embodiments, at least a part of the display 101 may be exposed through the front plate 102 that forms the first surface 110A and the first regions 110D. In certain embodiments, outlines (i.e., edges and corners) of the display 101 may have substantially the same form as those of the front plate 102. In another embodiment (not shown), the spacing between the outline of the display 101 and the outline of the front plate 102 may be substantially unchanged in order to enlarge the exposed area of the display 101.

In another embodiment (not shown), a recess or opening may be formed in a portion of a display area of the display 101 to accommodate at least one of the audio modules (e.g., the audio module 114), the sensor module 104, the camera module 105, and the light emitting device 106. In another embodiment (not shown), at least one of the audio modules (e.g., the audio module 114), the sensor module 104, the camera module 105, the sensor module 116 (e.g., a fingerprint sensor), and the light emitting device 106 may be disposed on the back of the display area of the display 101. In another embodiment (not shown), the display 101 may be combined with, or adjacent to, a touch sensing circuit, a pressure sensor capable of measuring the touch strength (pressure), and/or a digitizer for detecting a stylus pen. In certain embodiments, at least a part of the sensor modules 104 and 119 and/or at least a part of the key input devices 117 may be disposed in one of the first regions 110D and/or one of the second regions 110E.

The audio modules 103, 107 and 114 may correspond to a microphone hole (e.g., the audio module 103) and speaker holes (e.g., the audio modules 107 and 114). The microphone hole may contain a microphone disposed therein for acquiring external sounds and, in a case, contain a plurality of microphones to sense a sound direction. The speaker holes may be classified into an external speaker hole and a call receiver hole. In certain embodiments, the microphone hole and the speaker holes may be implemented as a single hole, or a speaker (e.g., a piezo speaker) may be provided without the speaker holes.

The sensor modules 104, 116 and 119 may generate electrical signals or data corresponding to an internal operating state of the electronic device 100 or to an external environmental condition. The sensor modules 104, 116 and 119 may include a first sensor module (e.g., the sensor module 104) (e.g., a proximity sensor) and/or a second sensor module (e.g., a fingerprint sensor) disposed on the first surface 110A of the housing 110, and/or a third sensor module (e.g., the sensor module 119) (e.g., a heart rate monitor (HRM) sensor) and/or a fourth sensor module (e.g., the sensor module 116) (e.g., a fingerprint sensor) disposed on the second surface 110B of the housing 110. The fingerprint sensor may be disposed on the second surface 110B as well as the first surface 110A (e.g., the display 101) of the housing 110. The electronic device 100 may further include at least one of a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, or an illuminance sensor.

The camera modules 105, 112 and 113 may include a first camera device (e.g., the camera module 105) disposed on the first surface 110A of the electronic device 100, and a second camera device (e.g., the camera module 112) and/or a flash (e.g., the camera module 113) disposed on the second surface 110B. The camera module 105 or the camera module 112 may include one or more lenses, an image sensor, and/or an image signal processor. The flash may include, for example, a light emitting diode or a xenon lamp. In certain embodiments, two or more lenses (infrared cameras, wide angle and telephoto lenses) and image sensors may be disposed on one side of the electronic device 100.

The key input devices 117 may be disposed on the lateral surface 110C of the housing 110. In another embodiment, the electronic device 100 may not include some or all of the key input devices 117 described above, and the key input devices 117 which are not included may be implemented in another form such as a soft key on the display 101. In certain embodiments, the key input devices 117 may include the sensor module 116 disposed on the second surface 110B of the housing 110.

The light emitting device 106 may be disposed on the first surface 110A of the housing 110, for example. For example, the light emitting device 106 may provide status information of the electronic device 100 in an optical form. In certain embodiments, the light emitting device 106 may provide a light source associated with the operation of the camera module 105. The light emitting device 106 may include, for example, a light emitting diode (LED), an infrared (IR) LED, or a xenon lamp.

The connector holes 108 and 109 may include a first connector hole (e.g., the connector hole 108) adapted for a connector (e.g., a universal serial bus (USB) connector) for transmitting and receiving power and/or data to and from an external electronic device, and/or a second connector hole (e.g., the connector hole 109) adapted for a connector (e.g., an earphone jack) for transmitting and receiving an audio signal to and from an external electronic device.

Referring to FIG. 1C, an electronic device may include a lateral bezel structure 121, a first support member 121-1 (e.g., a bracket), a front plate 122, a display 123, a printed circuit board (PCB) 124, a battery 125, a second support member 126 (e.g., a rear case), an antenna 127, and a rear plate 128. In certain embodiments, the electronic device 100 may omit at least one (e.g., the first support member 121-1 or the second support member 126) of the above components or may further include another component. Some components of the electronic device 100 may be the same as or similar to those of the electronic device 100 shown in FIG. 1A or FIG. 1B, thus, descriptions thereof are omitted below.

The first support member 121-1 is disposed inside the electronic device 100 and may be connected to, or integrated with, the lateral bezel structure 121. The first support member 121-1 may be formed of, for example, a metallic material and/or a non-metal (e.g., polymer) material. The first support member 121-1 may be combined with the display 123 at one side thereof and also combined with the PCB 124 at the other side thereof. On the PCB 124, a processor, a memory, and/or an interface may be mounted. The processor may include, for example, one or more of a central processing unit (CPU), an application processor (AP), a graphics processing unit (GPU), an image signal processor (ISP), a sensor hub processor, or a communications processor (CP).

The memory may include, for example, volatile memory or non-volatile memory.

The interface may include, for example, a high definition multimedia interface (HDMI), a USB interface, a secure digital (SD) card interface, and/or an audio interface. The interface may electrically or physically connect the electronic device 100 with an external electronic device and may include a USB connector, an SD card/multimedia card (MMC) connector, or an audio connector.

The battery 125 is a device for supplying power to at least one component of the electronic device 100, and may include, for example, a non-rechargeable primary battery, a rechargeable secondary battery, or a fuel cell. At least a part of the battery 125 may be disposed on substantially the same plane as the PCB 124. The battery 125 may be integrally disposed within the electronic device 100, and may be detachably disposed from the electronic device 100.

The antenna 127 may be disposed between the rear plate 128 and the battery 125. The antenna 127 may include, for example, a near field communication (NFC) antenna, a wireless charging antenna, and/or a magnetic secure transmission (MST) antenna. The antenna 127 may perform short-range communication with an external device, or transmit and receive power required for charging wirelessly. An antenna structure may be formed by a part or combination of the lateral bezel structure 121 and/or the first support member 121-1.

As noted above, the aesthetic appearance of the electronic device 100 can be improved by forming a micropattern on the housing 110.

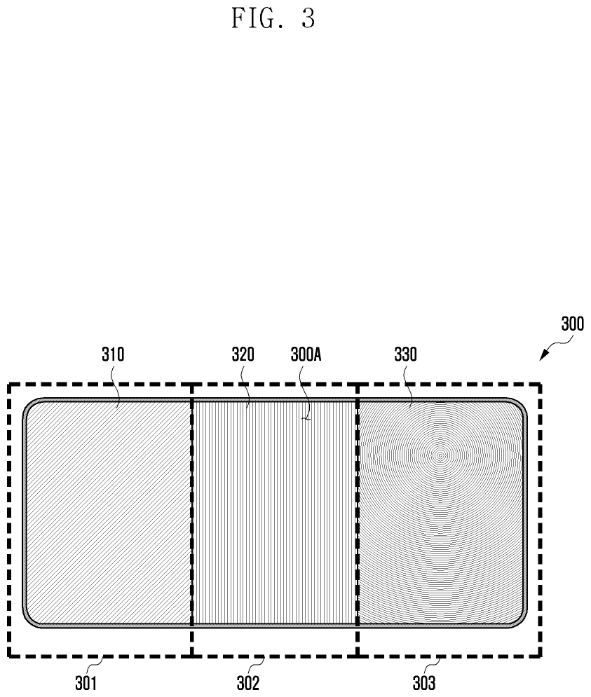

FIG. 2 and FIG. 3 are perspective views of a cover plate according to certain embodiments disclosed in the disclosure.

According to certain embodiments, for example, a cover plate 200 illustrated in FIG. 2 may be the rear plate 1111 illustrated in FIG. 1B or the rear plate 128 illustrated in FIG. 1C, and may be disposed on one surface (e.g., the second surface 110B of FIG. 1B or the rear surface of an electronic device) of an electronic device (e.g., the electronic device 100 of FIG. 1A).

The cover plate 200 may block various components included in an electronic device from the outside. The cover plate 200 disposed on one surface of an electronic device may form the external appearance of an electronic device. In the above, it is described that the cover plate 200 is disposed on the rear surface of an electronic device and is an element constituting the external appearance of an electronic device, but the cover plate 200 may be disposed on the front surface or side surfaces of an electronic device and may be disposed on various positions capable of constituting the external appearance of an electronic device.

The cover plate 200 may be manufactured in an injection molding method. In the foregoing process, a first pattern 210 and a second pattern 220 may be formed on the cover plate 200. The cover plate 200 may include multiple layers, and the first pattern 210 and the second pattern 220 may be formed on at least one of the multiple layers.

The first pattern 210 and the second pattern 220 may be formed to be seen through a first surface 200A of the cover plate 200. For example, the first pattern 210 and the second pattern 220 may be formed on the first surface 200A. Here, the first surface 200A of the cover plate 200 may mean an outer surface of the cover plate 200. The first pattern 210 may be a pattern formed in a first region 201 of the first surface 200A, and the second pattern 220 may be a pattern formed in a second region 202 of the first surface 200A. The first region 201 and the second region 202 may mean regions different from each other in the first surface 200A of the cover plate 200. In another embodiment, the first pattern 210 may be formed on a surface opposite to the first surface 200A. If the first surface 200A is the outer surface of a cover plate constituting the external appearance of an electronic device, the opposite surface of the first surface 200A may mean the inner surface of the cover plate. In addition, the first pattern 210 and second pattern 220 may be formed on both the first surface 200A and the opposite surface of the first surface 200A.

According to the shape of a pattern formed on the cover plate 200, it may be recognized that the cover plate 200 shows various textures. Since the shapes of reflection of light may be different according to the shapes of patterns, it may be possible to provide various a pleasing texture according to the shapes of patterns. For example, in a case where the first pattern 210 formed in the first region 201 and the second pattern 220 formed in the second region 202 of the cover plate 200 are patterns having different shapes, it may be recognized that the first region 201 and the second region 202 of the cover plate 200 show textures different from each other.

In some embodiments, a cover plate may include three or more different patterns. For example, as illustrated in FIG. 3, a first pattern 310 (diagonal lines) may be formed in a first region 301, a second pattern 320 (vertical lines) may be formed in a second region 302, and a third pattern 330 (circular lines) may be formed in a third region 303. In the case, it may be recognized that the first region 301, the second region 302, and the third region 303 of the cover plate 300 show textures different from each other.

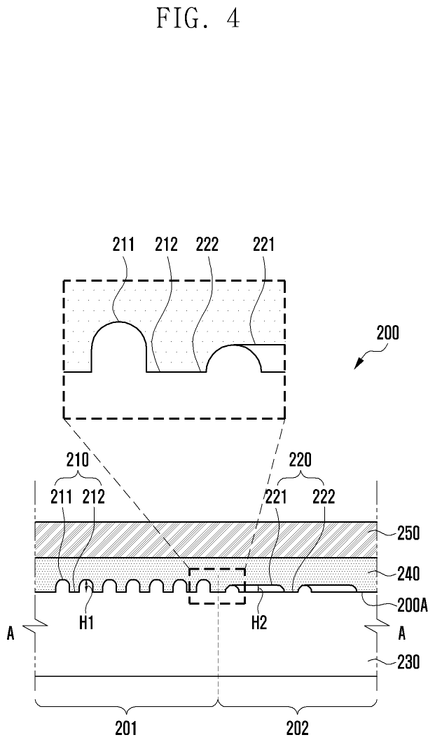

FIG. 4 is a partially cut cross sectional view of a cover plate taken along line A-A illustrated in FIG. 2, proximate to the center line where the first pattern 210 abuts the second pattern 220. The size ratio of elements illustrated in FIG. 4 are illustrated in some exaggeration for the convenience of description.

The cover plate 200 may include an injection molding product 230. The first pattern 210 and the second pattern 220 are formed in an intermediate layer 240. The intermediate layer is laminated on the injection molding product 230, and a painting layer 250 is laminated on the intermediate layer 240.

The intermediate layer 240 may include a brightness layer which enables the first pattern 210 and the second pattern 220 to more smoothly diffuse light. For example, the brightness layer may be made of a material capable of amplifying light diffusion. The brightness layer may be included in the intermediate layer 240 through deposition by various deposition methods (e.g., a chemical vapor deposition (CVD), a physics vapor deposition (PVD), or an atomic layer deposition (ALD)). According to a case, it may be possible that the brightness layer is laminated on the injection molding product 230 in a method of attaching a film-shaped material thereto.

The painting layer 250 may be a layer including a coating material which gives the cover plate 200 a specific color. In addition, the painting layer 250 may include a protective layer for protecting a coating material so as to prevent the coating material from being peeled off therefrom. In an embodiment, the intermediate layer 240 may be a layer including a material having an adhesive property which enables the painting layer 250 to smoothly adhere to the injection molding product 230, and a material (e.g., a putty, or primer) capable of compensating for a height difference therebetween.

The first pattern 210 and the second pattern 220 of the cover plate 200 may be a pattern formed on the injection molding product 230 included in the cover plate 200, but the injection molding product 230 may be an element included in the cover plate 200. Therefore, hereinafter, the first pattern 210 and the second pattern 220 will be described as a pattern formed on the cover plate 200 for the convenience of description.

Referring to FIG. 4, the first pattern 210 and second pattern 220 may be formed in different regions of the cover plate 200. The first pattern 210 may be a pattern formed in a first region 201, and the second pattern 220 may be a pattern formed in a second region 202. The first pattern 210 and the second pattern 220 may have shapes different from each other.

According to certain embodiments, the first pattern 210 may include a structure having a first flat part 212 and a first protrusion part 211 protruding at a first height H1 with respect to the first flat part 211. The first flat part 212 and the first protrusion part 211 can be repeatedly arranged, such that there are repeating patterns of first flat parts 212 and first protrusion parts 211, wherein each of repeated first protrusion parts 211 have substantially the first height H1. Alternatively, each of the first protrusion parts 211 can have heights that are within 5% deviation of the first height, or are within a deviation from the first height, where such deviation is visibly indiscernible, or cannot be discerned by touching.

In an embodiment, the protruded height H1 of the first protrusion part 211 may be about 1 μm to 3 μm. In another embodiment, the protruded height H1 of the first protrusion part 211 may be about 3 μm to 10 μm. The protruded height H1 of the first protrusion part 211 may be variously changed in addition to the above description.

The second pattern 220 may include a structure having a second flat part 221 and a second protrusion part 221 protruding at a second height, height H2, with respect to the second flat part 222, the second flat part 222. The second protrusion part 221 being repeatedly arranged, such that there are repeating patterns of second flat parts 222 and second protrusion parts 221, wherein each of repeated second protrusion parts 221 have substantially the second height H2. Alternatively, each of the second protrusion parts 221 can have heights that are within 5% deviation of the second height, or are within a deviation from the second height, where such deviation is visibly indiscernible, or cannot be discerned by touching.

In an embodiment, the protruded height H2 of the second protrusion part 221 may be about 1 μm to 3 μm. In another embodiment, the protruded height H2 of the second protrusion part 221 may be about 3 μm to 10 μm. The protruded height H2 of the second protrusion part 221 may be variously changed in addition to the above description.

The position relation (e.g., the interval) between the first protrusion part 211 and the first flat part 212 and the shapes (e.g., a width or protrusion height) thereof may be different from the position relation between the second protrusion part 221 and the second flat part 222 and the shapes thereof, respectively. According to an embodiment, the protruded height of the first protrusion part 211 and the protruded height of the second protrusion part 221 may be different from each other. The shapes of the first protrusion part 211 and the first flat part 212 may be different from the shapes the second protrusion part 221 and the second flat part 222, respectively, so that the first pattern 210 and the second pattern 220 become patterns different from each other. For example, the first pattern 210 may be a pattern including a curved-line, and the second pattern 220 may be a pattern including a straight-line. In the case, the first protrusion part 211 and the first flat part 212 of the first pattern 210 may be formed in a curved-line shape, the second protrusion part 221 and the second flat part 222 may be formed in a straight-line shape. Here, the curved-line may include a concentric circle, and the straight-line may include a horizontal-line, a vertical-line, and a diagonal-line with respect to the cover plate 200.

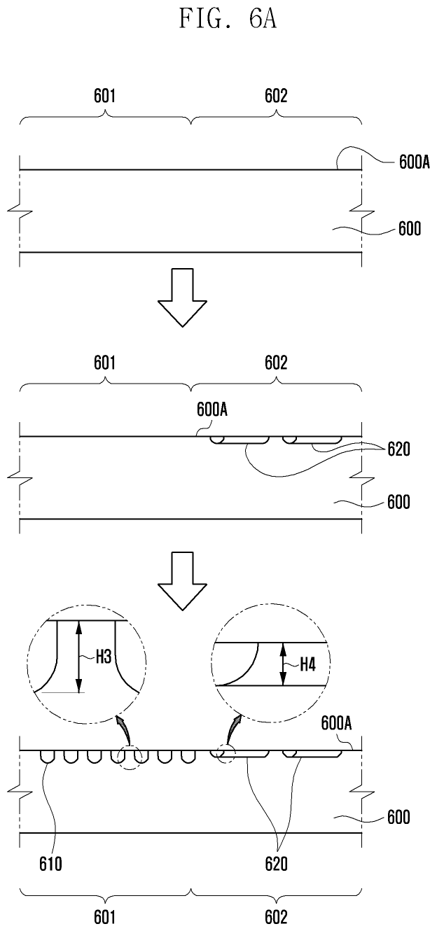

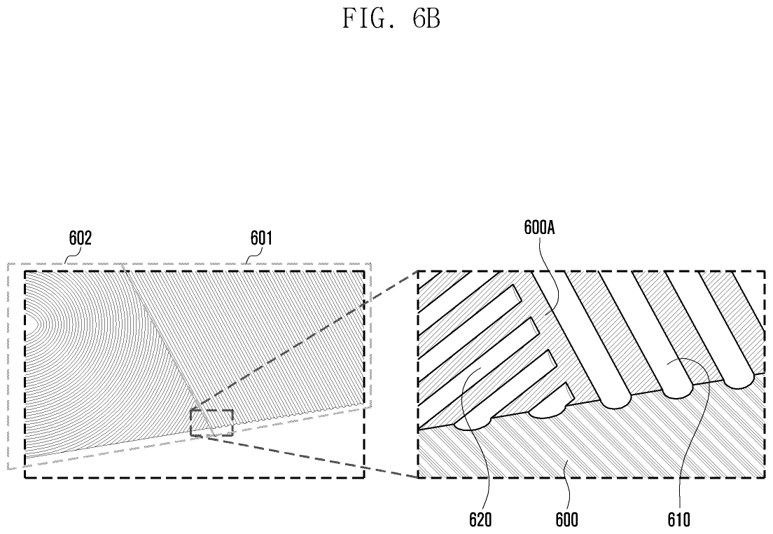

According to certain embodiments, in a portion at which the first pattern 210 and the second pattern 220 are connected to each other, the first flat part 212 of the first pattern 210 and the second flat part 222 of the second pattern 220 may be continuously connected to each other. For example, a height difference or interval may not be formed between the first flat part 212 and the second flat part 222. The first pattern 210 and the second pattern 220 formed on the cover plate 200 may be formed by mold patterns (e.g., the first mold pattern 610 and the second mold pattern 620 of FIG. 6A) formed on one mold core (e.g., the first mold core 600 of FIG. 6A), respectively, so that the connected portion thereof is continuously formed. Detailed descriptions about the process in which the cover plate 200 including the first pattern 210 and the second pattern 220 is injection-molded will be described below.

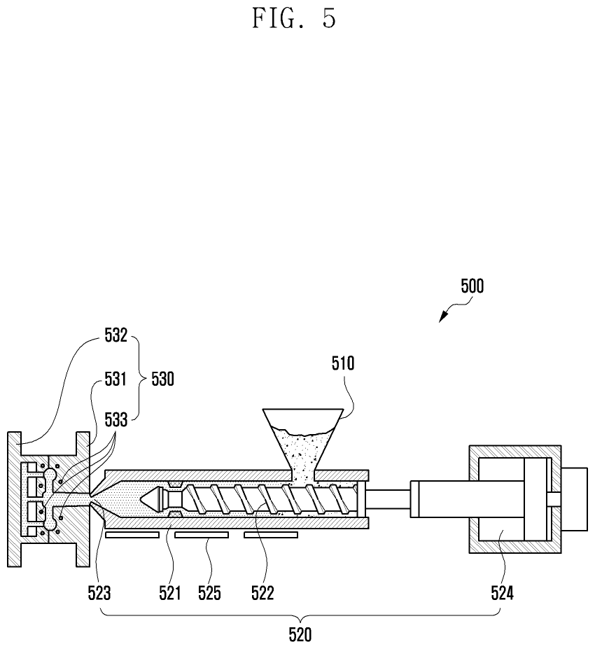

FIG. 5 is a schematic view of an injection device for manufacturing a cover plate 200 according to certain embodiments disclosed in the disclosure.

Referring to FIG. 5, an injection device 500 may include a mold part 530, a storage part 510, and a providing part 520.

According to certain embodiments, the storage part 510 may include a space in which an injection material is stored. The injection material stored in the storage part 510 may be a solid state or an at least partially melted state. The injection material may be a polymer material. For example, a polymer compound such as a synthetic resin may be used as the injection material. The injection material may be an at least partially transparent material in a coagulated state. For example, the injection material may be a material having about 70% of the transmittance or more when coagulated such that an optical diffusion or a prism phenomenon occurs by patterns (e.g., the patterns 210 and 220 of FIG. 2) of a cover plate (e.g., the cover plate 200 of FIG. 2) manufactured by an injection molding.

The providing part 520 may provide the injection material stored in the storage part 510 to the mold part 530. The providing part 520 may include a pipe conduit 521 which the injection material of the storage part 510 is introduced into and temporary stores in, a pressing device 522 configured to push out the injection material stored in the pipe conduit 521 in the direction of the mold part 530, and a nozzle 523 configured to connect the pipe conduit 521 and the mold part 530. For example, the pressing device 522 may be a screw connected to a hydraulic cylinder 524. The hydraulic cylinder 524 may push out the screw in the direction of the nozzle 523 so that the screw rotates. Therefore, the injection material stored in the pipe conduit 521 may be pressed in the direction of the nozzle 523. The pipe conduit 521 may have a heater installed therein to change the injection material stored in the pipe conduit 521 into a liquid state or to maintain the liquid state thereof.

The mold part 530 may include a first mold core 531, a second mold core 532, and a cooling channel 533. The injection material introduced from the providing part 520 may be injected between the first mold core 531 and the second mold core 532. When an injection material has been injected, the first mold core 531 and the second mold core 532 may be cooled by a coolant supplied through the cooling channel 533 so that the injected injection material coagulates, and thus the injection molding may be completed.

The injection device 500 described above may be merely a general example of a device for an injection molding, and various injection devices 500 may be used for manufacturing the cover plate of the disclosure within a range obvious to a person skilled in the art.

FIG. 6A is a view, which is schematized as a cross sectional view, illustrating a process of forming a mold pattern according to certain embodiments disclosed in the disclosure. FIG. 6B is a perspective view of a first mold core according to certain embodiments disclosed in the disclosure.

Hereinafter, it will be described under an assumption that a cover plate manufactured in an injection molding method by a first mold core 600 is the cover plate illustrated in FIG. 2. In descriptions related to a cover plate and patterns formed on the cover plate, the same reference numerals as those of FIG. 2 will be used.

A first mold pattern 610 and a second mold pattern 620 may be formed on one surface 600A of a first mold core 600. The first mold pattern 610 may be a mold pattern formed in a shape corresponding to the first pattern 210 formed on the cover plate 200, and the second mold pattern 620 may be a mold pattern formed in a shape corresponding to the second pattern 220 formed on the cover plate 200. The first mold pattern 610 and the second mold pattern 620 may be formed to have shapes different from each other. For example, the first mold pattern 610 may be a pattern including a curved-line, and the second mold pattern 620 may be a pattern including a straight-line. In the case, the first pattern 210 formed by the first mold pattern 610 may become a pattern including a curved-line, and the second pattern 220 formed by the second mold pattern 620 may become a pattern including a straight-line.

Referring to FIG. 6A and FIG. 6B, the first mold pattern 610 may be formed in a first region 601 of the one surface 600A of the first mold core 600, and the second mold pattern 620 may be formed in a second region 602 of the one surface 600A of the first mold core 600. The cover plate 200 disclosed in the disclosure may be formed through an injection molding by the first mold core 600 including the first mold pattern 610 and the second mold pattern 620.

When an injection material is injected into the first mold core 600 including the first mold pattern 610 and the second mold pattern 620, the first pattern 210 may be formed by the first mold pattern 610, and the second pattern 220 may be formed by the second mold pattern 620.

As illustrated in FIG. 6A and FIG. 6B, both the first mold pattern 610 and the second mold pattern 620 may be formed on the one surface 600A of the first mold core 600. Therefore, as illustrated in FIG. 4, the first pattern 210 and the second pattern 220 of the cover plate 200 injection-molded by the first mold core 600 may have a continuously connected shape.

The first mold pattern 610 and the second mold pattern 620 may be formed in various shapes according to a machining method. For example, the first mold pattern 610 may be formed to have the depth H3 of 1 μm to 3 μm with respect to a reference surface of the first mold core 600. In addition, the first mold pattern 610 may be formed to have the depth H3 of 3 μm to 10 μm with respect to the reference surface of the first mold core 600. For example, the second mold pattern 620 may be formed to have the depth H4 of 1 μm to 3 μm with respect to the reference surface of the first mold core 600. In addition, the second mold pattern 620 may be formed to have the depth H4 of 3 μm to 10 μm with respect to the reference surface of the first mold core 600. In addition, the depth H3 of the first mold pattern 610 and the depth H4 of the second mold pattern may be different.

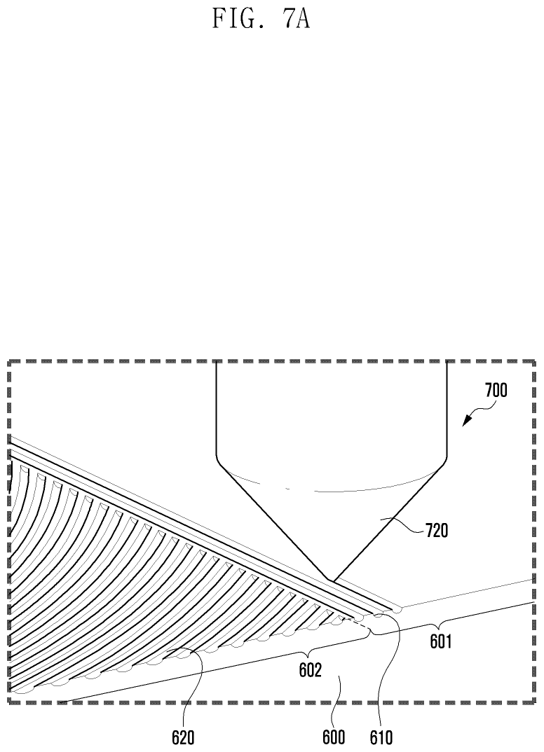

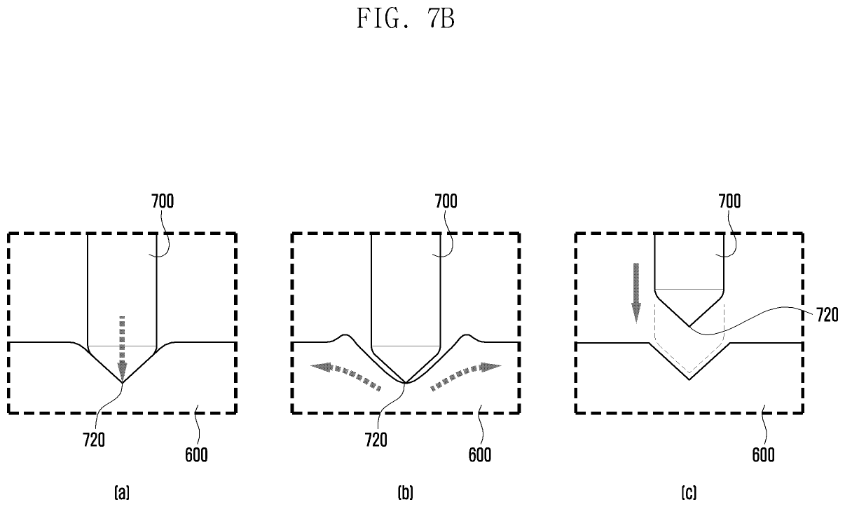

FIG. 7A and FIG. 7B are views illustrating a machining process of a first mold core according to certain embodiments disclosed in the disclosure.

The first mold pattern 610 and second mold pattern 620 may be formed in regions different from each other on the previously substantially flat one surface 600A of the first mold core 600 by one the same machining tool 700. The machining tool 700 may relatively move with respect to the first mold core 600 by a movement part (not shown) according to computer control, to form the first mold pattern 610 and the second mold pattern 620. For example, the movement part may mean a device for transferring the machining tool 700, may mean a device for transferring the first mold core 600, and in some cases, may mean a device for transferring both the machining tool 700 and the first mold core 600.

The first mold pattern 610 may be formed in the first region 601 of the first mold core 600 by a tip 720 of the machining tool 700, and the second mold pattern 620 may be formed in the second region 602. In the case, the tip 720 of the machining tool 700 may move forming the first mold pattern 610 and the second mold pattern 620 by pressing a portion of the first mold core 600 instead of cutting a portion the first mold core 600 to form the first mold pattern 610 and the second mold pattern 620. By using the above machining method, it may be possible to form two types of patterns different from each other on the first mold core 600 through one or the same machining tool 700.

According to certain embodiments, as illustrated in (a) of FIG. 7B, when the tip 720 of the machining tool 700 presses a portion of the first region 601 of the first mold core 600, the pressed portion may be more compressed than an unpressed portion so that the first mold pattern 610 is formed. When the tip 720 of the machining tool 700 presses a portion of the second region 602 of the first mold core 600, the pressed portion may be more compressed than an unpressed portion so that the second mold pattern 620 is formed.

According to certain embodiments, as illustrated in (b) of FIG. 7B, when the tip 720 of the machining tool 700 presses a portion of the first region 601 of the first mold core 600, a material constituting the first mold core 600 may be pushed out of the pressed portion so that the first mold pattern 610 is formed. When the tip 720 of the machining tool 700 presses a portion of the second region 602 of the first mold core 600, a material constituting the first mold core 600 may be pushed out of the pressed portion so that the second mold pattern 620 is formed.

The machining method described above is a method in which the tip 720 of the machining tool 700 continuously moves in a state of pressing the first mold core 600, whereas, as illustrated (c) of in FIG. 7C, the tip 720 of the machining tool 700 may hit a portion of first region 601 of the first mold core 600 so that the first mold pattern 610 is formed. The tip 720 of the machining tool 700 may hit a portion of the second region 602 of the first mold core 600 so that the second mold pattern 620 is formed. The method in which the first mold pattern 610 and the second mold pattern 620 are formed by the above hitting may form a pattern having a deeper depth rather than the method in which the machining tool 700 continuously moves in a state of pressing the first mold core 600.

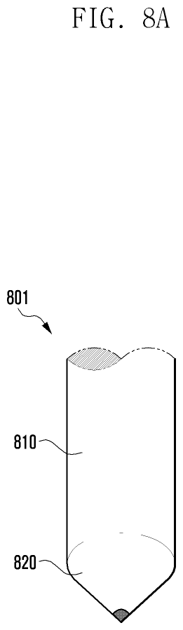

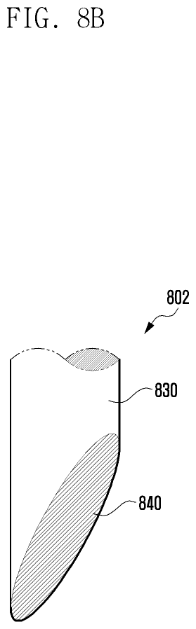

FIG. 8A and FIG. 8B are views illustrating a machining tool according to certain embodiments disclosed in the disclosure.

According to certain embodiments, machining tools 801 and 802 for machining the first mold pattern 610 and the second mold pattern 620 may include machining bodies 810 and 830, and tips 820 and 840, respectively.

According to certain embodiments, the machining tool 801 illustrated in FIG. 8A may be a machining tool 801 including the tip 820 which does not have a directionality. According to certain embodiments, the tip 820 may be symmetrically formed on the machining body 810 such that the tip 820 does not have a directionality with respect to a moving direction of the machining tool 801. For example, as illustrated in FIG. 8A, the tip 820 may be formed in a conical shape. In a case where the tip 820 of the machining tool 801 does not have a directionality, it may be possible to form a first mold pattern (e.g., the first mold pattern 610 of FIG. 6A) and a second mold pattern (e.g., the second mold pattern 620 of FIG. 6A), by relatively moving the machining tool 801 with respect to a first mold core (e.g., the first mold core 600 of FIG. 6A) by using a moving device having a simple degree of freedom of movement. In the case, the moving device may not move a first mold core and may move only the machining tool 801, to continuously form a first mold pattern and a second mold pattern on a first mold core.

According to certain embodiments, as illustrated in FIG. 8B, the machining tool 802 may include the machining body 830 and the tip 840 formed eccentrically in a direction thereof with respect to the machining body 830. In the case, the tip 840 of the machining tool 802 may have a directionality with respect to a moving direction of the machining tool 802. The machining direction of the machining tool 802 having such the shape may be determined. There may be a case that the case where such the machining tool 802 should use a moving device having a somewhat complex degree of freedom of movement rather than the case where a machining tool (e.g., the machining tool 801 of FIG. 8A), which does not have a directionality, is used.

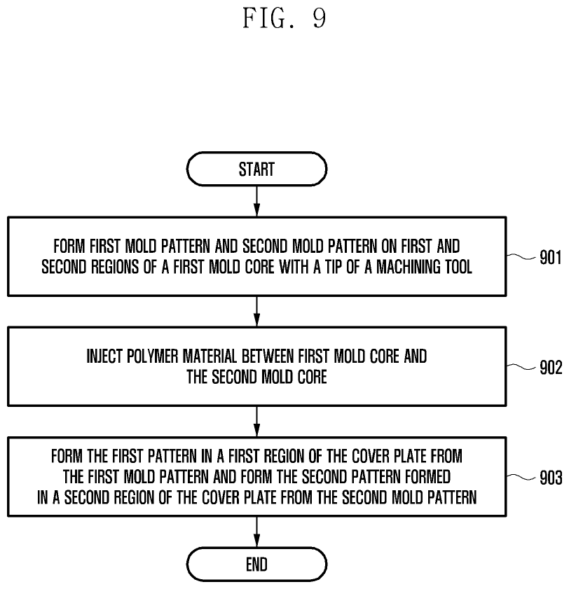

FIG. 9 is a view illustrating a method for manufacturing a cover plate according to various embodiments disclosed in the disclosure.

In the following description, the same reference number are used to refer to the same or similar components as those described above.

The first mold pattern 610 and the second mold pattern 620 may be continuously formed in the first region 601 and the second region 602 of the first mold core 600, respectively. The first mold pattern and the second mold pattern may be formed on the first mold core 600 using the tip 720 of the machining tool 700 (901). For the detailed description of the process of forming the first mold pattern and the second mold pattern on the first mold core 600, refer to the descriptions of FIGS. 7A, 7B and 8.

Injection molding may be performed by injecting an injection product between the first mold core 600 and the second mold core 532 (902). The injection-molded product injected between the first mold core 600 and the second mold core 532 may be the cover plate 200.

In the injection molding process, the first pattern 210 may be formed in the first region 201 of the cover plate 200 by the first pattern 210 formed on the first mold core 600, and the second pattern 220 may be formed in the second region 202 of the cover plate 200 by the second pattern 220 formed on the first mold core 600 (903).

Meanwhile, in the above, it is described that a first mold pattern (e.g., the first mold pattern 610 of FIG. 6A) and a second mold pattern (e.g., the second mold pattern 620 of FIG. 6A) is formed on a first mold core (e.g., the first mold core 600 of FIG. 6A), but three types of mold patterns or more may be formed on a first mold core. For example, in a case where a cover plate is manufactured using a first mold core including three types of mold patterns, as illustrated in FIG. 3, the cover plate 300 including three types of patterns (e.g., the first pattern 310, the second pattern 320, and the third pattern 330 of FIG. 3) may be manufactured.

A cover plate of an electronic device according to certain embodiments disclosed in the disclosure may include a first pattern formed in a first region of the cover plate and a second pattern formed in a second region of the cover plate, wherein the first pattern has a first flat part and a first protrusion part configured to protrude at predetermined height with respect to the first flat part, the first flat part and the first protrusion part being repeatedly arranged, the second pattern has a second flat part and a second protrusion part configured to protrude at predetermined height with respect to the second flat part, the second flat part and the second protrusion part being repeatedly arranged, and the first flat part of the first pattern and the second flat part of the second pattern are continuously joined to each other at a portion at which the first pattern and the second pattern are connected.

In addition, the first pattern may be a pattern including a curved-line, and the second pattern may be a pattern including a straight-line.

In addition, a height of the first protrusion part of the first pattern and a height of the second protrusion part of the second pattern may be different from each other.

In addition, a height of the first protrusion part of the first pattern may be 1 μm to 3 μm inclusive, and a height of the second protrusion part of the second pattern may be 1 μm to 3 μm inclusive.

In addition, a height of the first protrusion part of the first pattern may be 3 μm to 10 μm inclusive, and a height of the second protrusion part of the second pattern may be 3 μm to 10 μm inclusive.

FIG. 9 described a method according to certain embodiments of the disclosure. At operation 905, (see FIG. 7A) a tip 720 of a machining tool 700 forms a first mold pattern 610 and a second mold pattern 620 on first and second regions 601, 602, respectively of a first mold core 600.

The first and second mold patterns 610 and 620 can be formed by moving the tip 720 of the machining tool 700 or by hitting the portions of the first mold core 600.

The first mold pattern 610 can have a first depth with respect to a reference surface of the first mold core 600 and the second mold pattern 620 can have a second depth with respect to the reference surface of the first mold core 600, wherein the first depth and the second depth are different from each other.

In certain embodiments, the first mold pattern and the second mold pattern have a depth of 1 μm to 3 μm inclusive with respect to the reference surface.

At operation 910, a polymer material is injected between the first mold core 600 and a second mold core 532.

As a result, a cover plate for an electronic device 200 is formed at operation 915, having a first pattern 210 formed from the first mold pattern 610 in a first region 201 of the cover plate 200 (operation 920), and a second pattern 220 formed from the second mold pattern 620 in a second region 202 of the cover plate 200 (operation 925).

According to certain embodiments, a cover plate of an electronic device, comprises: a first pattern formed in a first region of the cover plate; and a second pattern formed in a second region of the cover plate, wherein the first pattern has a first flat part and a first protrusion part protruding at a first height with respect to the first flat part, the first flat part and the first protrusion part being repeatedly arranged, the second pattern has a second flat part and a second protrusion part protruding at a second height with respect to the second flat part, the second flat part and the second protrusion part being repeatedly arranged, and the first flat part of the first pattern and the second flat part of the second pattern are continuously joined to each other at a portion at which the first pattern and the second pattern are connected.

According to certain embodiments the first pattern is a pattern comprising a curved-line, and the second pattern is a pattern comprising a straight-line.

According to certain embodiments, the first height and the second height are different from each other.

According to certain embodiments, the first height is between 1 μm to 3 μm, and the second height is between 1 μm to 3 μm.

According to certain embodiments, the first height is between 3 μm to 10 μm, and the second height is between 3 μm to 10 μm.

According to certain embodiments, a method comprises forming a cover plate on an electronic device by molding a polymer material using a first mold core and a second mold core, forming a first pattern using a first mold pattern in a first region of one surface of a first mold core, and forming a second pattern using a second mold pattern in a second region of the one surface of the first mold core.

According to certain embodiments, forming the cover plate comprises injecting the polymer material between the first mold core and the second mold core.

According to certain embodiments, the method further comprises continuously forming the first mold pattern and the second mold pattern using a same machining tool.

According to certain embodiments, forming the first mold pattern and the second mold pattern further comprises: moving a tip of the same machining tool to press a portion of the first region of the one surface of the first mold core, and moving the tip of the same machining tool to press a portion of the second region of the one surface of the first mold core.

According to certain embodiments, the first mold pattern has a first depth with respect to a reference surface of the first mold core and the second mold pattern has a second depth with respect to the reference surface of the first mold core, wherein the first depth and the second depth are different from each other.

According to certain embodiments, the first mold pattern and the second mold pattern have a depth of 1 μm to 3 μm inclusive with respect to a reference surface.

According to certain embodiments, the pressed portion of the first portion is more compressed than an unpressed portion of the first portion, and the pressed portion of the second region is more compressed than an unpressed portion of the second portion.

According to certain embodiments, moving the tip of the same machining tool to press the portion of the first region further comprises pushing material constituting the first mold core out of the pressed portion, and moving a tip of the same machining tool to press the portion of the second region further comprises pushing material constituting the second mold core out of the pressed portion.

According to certain embodiments, continuously forming the first mold pattern and the second mold pattern further comprises hitting a portion of the first region of the one surface of the first mold core with a tip of the same machining tool, and hitting a portion of the second region of the one surface of the first mold core with the tip of the same machining tool.

According to certain embodiments, the first mold pattern has a first depth with respect to a reference surface of the first mold core and the second mold pattern has a second depth with respect to the reference surface, and wherein the first depth and the second depth are different from each other.

According to certain embodiments, the first depth and the second depth are between 3 μm to 10 μm inclusive with respect to the reference surface of the first mold core.

According to certain embodiments, the first mold pattern comprises a curved-line, and the second mold pattern is a pattern comprises a straight-line.

According to certain embodiments, the same machining tool comprises a machining body and a tip symmetrically formed at an end of the machining body.

According to certain embodiments, the tip of the same machining tool has a conical shape at the machining body.

According to certain embodiments, the polymer material is a transparent material that is partially transmissive in a coagulated state.

Embodiments of the disclosure disclosed in the specification and the drawings are merely specific examples presented to easily describe the technical content according to embodiments of the disclosure and to help understanding of the disclosure, and are not intended to limit the scope of embodiments of the disclosure. Accordingly, it should be interpreted that the scope of certain embodiments of the disclosure includes not only embodiments disclosed herein, but also all changed or modified forms derived based on the technical idea of certain embodiments of the disclosure.

1. A cover plate of an electronic device, the cover plate comprising:
a first pattern formed in a first region of the cover plate; and
a second pattern formed in a second region of the cover plate, wherein
the first pattern has a first flat part and a first protrusion part protruding at a first height with respect to the first flat part, the first flat part and the first protrusion part being repeatedly arranged,
the second pattern has a second flat part and a second protrusion part protruding at a second height with respect to the second flat part, the second flat part and the second protrusion part being repeatedly arranged, and
the first flat part of the first pattern and the second flat part of the second pattern are continuously joined to each other at a portion at which the first pattern and the second pattern are connected.

2. The cover plate of claim 1, wherein the first pattern is a pattern comprising a curved-line, and
the second pattern is a pattern comprising a straight-line.

3. The cover plate of claim 1, wherein the first height and the second height are different from each other.

4. The cover plate of claim 1, wherein the first height is between 1 μm to 3 μm, and
wherein the second height is between 1 μm to 3 μm.

5. The cover plate of claim 1, wherein the first height is between 3 μm to 10 μm, and
wherein the second height is between 3 μm to 10 μm.

6. An method comprising:
forming a cover plate on an electronic device by molding a polymer material using a first mold core and a second mold core,
forming a first pattern using a first mold pattern in a first region of one surface of a first mold core, and
forming a second pattern using a second mold pattern in a second region of the one surface of the first mold core.

7. The method of claim 6, forming the cover plate comprises injecting the polymer material between the first mold core and the second mold core.

8. The method of claim 6, further comprising continuously forming the first mold pattern and the second mold pattern using a same machining tool.

9. The method of claim 8, wherein the continuously forming the first mold pattern and the second mold pattern further comprises:
moving a tip of the same machining tool to press a portion of the first region of the one surface of the first mold core, and
moving the tip of the same machining tool to press a portion of the second region of the one surface of the first mold core.

10. The method of claim 8, wherein the first mold pattern has a first depth with respect to a reference surface of the first mold core and the second mold pattern has a second depth with respect to the reference surface of the first mold core, wherein the first depth and the second depth are different from each other.

11. The method of claim 8, wherein the first mold pattern and the second mold pattern have a depth of 1 μm to 3 μm inclusive with respect to a reference surface.

12. The method of claim 9, wherein the pressed portion of the first portion is more compressed than an unpressed portion of the first portion, and
wherein the pressed portion of the second region is more compressed than an unpressed portion of the second portion.

13. The method of claim 9, wherein moving the tip of the same machining tool to press the portion of the first region further comprises pushing material constituting the first mold core out of the pressed portion, and
moving a tip of the same machining tool to press the portion of the second region further comprises pushing material constituting the second mold core out of the pressed portion.

14. The electronic device of claim 8, wherein continuously forming the first mold pattern and the second mold pattern further comprises hitting a portion of the first region of the one surface of the first mold core with a tip of the same machining tool, and
hitting a portion of the second region of the one surface of the first mold core with the tip of the same machining tool.

15. The method of claim 14, wherein the first mold pattern has a first depth with respect to a reference surface of the first mold core and the second mold pattern has a second depth with respect to the reference surface, and wherein the first depth and the second depth are different from each other.

16. The method of claim 15, wherein the first depth and the second depth are between 3 μm to 10 μm inclusive with respect to the reference surface of the first mold core.

17. The method of claim 6, wherein the first mold pattern comprises a curved-line, and
the second mold pattern is a pattern comprises a straight-line.

18. The method of claim 8, wherein the same machining tool comprises a machining body and a tip symmetrically formed at an end of the machining body.

19. The method of claim 18, wherein the tip of the same machining tool has a conical shape at the machining body.

20. The method of claim 6, wherein the polymer material is a transparent material that is partially transmissive in a coagulated state.
